(19) United States
(12) Patent Application Publication
(10) Pub. No.: US 2004/0174098 A1
(43) Pub. Date: Sep. 9, 2004

(54) Optimized piezoelectric transformer apparatus with maximum energy conversion efficiency

(76) Inventors: Yu-Hsiang Hsu, Taipei (TW); Wen-Hsin Hsiao, Shituen Chiu (TW); Wen-Jong Wu, Junghe City (TW); Chih-Kung Lee, Taipei (TW)

Correspondence Address: J.C. Patents, Suite 250, 4 Venture, Irvine, CA, 92618, US

(21) Appl. No.: 10/793,837

(22) Filed: Mar. 4, 2004

Related U.S. Application Data
(60) Provisional application No. 60/452,197, filed on Mar. 4, 2003.

(51) Int. Cl. H01L 41/107

(52) U.S. Cl. 310/366

(57) ABSTRACT

A piezoelectric transformer apparatus is disclosed for converting electrical input energy into output for driving a load under optimized conditions. The transformer apparatus comprises at least one actuator section and at least one sensor section. The at least one actuator section has a modal-shaped electrode for optimized electrical-to-mechanical energy conversion for exciting mechanical vibration in the apparatus. The at least one sensor section has a sensor electrode with the electrical impedance of output static capacitance thereof matched to impedance of the load for optimized conversion of the energy of said excited mechanical vibration into electrical energy for driving said load.

### CROSS-REFERENCE TO RELATED APPLICATION

This application claims the priority benefits of U.S. provisional application titled “OPTIMIZED PIEZOELECTRIC TRANSFORMER APPARATUS WITH MAXIMUM ENERGY CONVERSION EFFICIENCY” filed on Mar. 4, 2003, serial No. 60/452,197. All disclosure of this application is incorporated herein by reference.

### BACKGROUND OF THE INVENTION

1. Field of the Invention

This invention relates in general to piezoelectricity and, in particular, to the optimization of energy conversion efficiency in piezoelectric devices. More particularly, this invention relates to the construction of a piezoelectric transformer apparatus for operation at maximized energy conversion efficiency.

2. Technical Background

Piezoelectricity is useful in various applications. With the advancements in material science and microelectronic technology, piezoelectric apparatuses are found in ever more equipment including scientific, industrial and commercial applications. One of the important applications of the piezoelectric device is the utilization as power transformer for various electronic equipments. Typical examples include piezoelectric transformer in the power system of portable devices such as notebook computers, personal digital assistant (PDA), and cellular phones, among others.

A piezoelectric transformer is, inherently, a mechanically and electrically coupled system, which performs voltage conversion by sustained resonance inside its finite bulk structure. In a piezoelectric transformer system, conversion of electric power is facilitated via the actuator (input) and sensor (output) electrodes adhered to the surface of the piezoelectric workpiece that establish specific electrical/mechanical energy conversion characteristics for the system.

Since energy sourcing capability is one of the main considerations for a piezoelectric transformer, interface circuit connected to the piezoelectric workpiece is typically more than circuits such a charge or current amplifier that utilizes pseudo-ground to decouple electrical effects off the system. Typically, a suitable electrical circuit for a piezoelectric transformer system is highly dependent on the electro-mechanical coupling characteristic of the piezoelectric workpiece.

First piezoelectric transformers proposed by C. A. Rosen in the 1950s were slender piezoelectric workpieces operating in the longitudinal vibration mode. These were free-free workpieces with both longitudinal ends left mechanically unconnected and supported at nodal points in their operating resonance modes. In these piezoelectric transformer devices, one half of their structure was utilized as actuator and the other as sensor. FIG. 1 schematically illustrates such a conventional free-free workpiece 11 together with the internal vibration wave distribution. Frequently they were operated in the lambda mode—resonating in the second mode of longitudinal vibration and sustaining one full cycle of strain distribution inside the workpiece. Analysis of these early Rosen-type piezoelectric transformers 11 was based on the mathematical modeling of finite structural resonance mode in bulk motion so as to implement transformation of low AC input voltage into high AC output. In the model, actuator 12 of a Rosen-type piezoelectric transformer sinks the input electric energy under half-period mode-two strain distribution, and sensor 13 thereof sources the mechanical energy within the other half period of mode-two strain for output.

As is known, early Rosen-type piezoelectric transformers were not limited to mode-two devices. Based on Rosen's works, other variants such as third-order longitudinal-mode devices (FIG. 2A), alternately-poled devices (FIG. 2B) and center-drive half-lambda-mode devices (FIG. 2C) were proposed. However, all these traditional piezoelectric transformer designs suffered from fundamental drawbacks. The fact that they were fundamentally Rosen-type devices tied them to the limitations embedded within the very mechanical design concept, which rested on the basic mathematical modeling employed.

Traditional analyses for piezoelectric transformer workpiece design were based on the theory of electric circuit. Equivalent circuits for considered piezoelectric transformer workpiece designs were established simulating the motion of the workpieces in an electric circuit system. Mathematical modeling of the equivalent circuit for such a circuit simulation resolved into a set of ordinary differential equations that described the system in the terms of pure circuit theory.

However, such traditional approaches of developing piezoelectric transformers for various specific applications had been found to have shortfalls. For example, due to the presence of the infinite resonance modes for any piezoelectric system, a workpiece developed suffers difficulties in entering into the right mode of resonance. Sophisticated support circuitry has to be integrated into a piezoelectric transformer system so as to ensure the workpiece entrance into the desired mode of resonance. Further, electrical and mechanical characteristics of the piezoelectric material used for making workpieces are functions of environmental factors including humidity and temperature. Quality factor and resonance frequency of a workpiece drift considerably when any of these factors is altered. Such problems have hindered the wide commercial acceptance of piezoelectric transformers.

### SUMMARY OF THE INVENTION

There is therefore a need for a method for the optimization of transfer of power across the electrical and mechanical forms in a piezoelectric transformer apparatus.

There is also a need for a design method for ensuring the mass production of an optimized piezoelectric transformer apparatus capable of operating in an optimal condition to the requirement of any specific load characteristics.

A piezoelectric transformer is a mechanical structure operating simultaneously in spatial and time domains. That is, its governing equations are described by a set of partial differential equations (PDEs). Operating efficiency of traditional piezoelectric transformers has not been optimized due to the absence of spatial information in the mathematical analysis system based on traditional theory of equivalent circuit. The piezoelectric transformer apparatus of the present invention, in comparison, is optimized both mechanically and electrically. A system of design principle based on the teaching of the present invention allows the construction of piezoelectric transformer apparatuses that operate in optimal conditions such as, maximized power transfer efficiency.

In accordance with the present invention, an optimized piezoelectric transformer apparatus has one or more actuator inputs that are optimized by using modal actuators to match the mechanical strain thereof. Sensor output of the transformer apparatus is optimized by the matching of output impedance thereof to the load impedance. Such an inventive piezoelectric transformer apparatus is forced to operate under the condition of optimized energy transfer efficiency.

In accordance with the present invention, a piezoelectric transformer apparatus is used for converting electrical input energy into output for driving a load under optimized conditions. The transformer apparatus comprises at least one actuator section and at least one sensor section. The at least one actuator section has a modal-shaped electrode for optimized electrical-to-mechanical energy conversion for exciting mechanical vibration in the apparatus. The at least one sensor section has a sensor electrode with the electrical impedance of output static capacitance thereof matched to impedance of the load for optimized conversion of the energy of said excited mechanical vibration into electrical energy for driving said load.

### BRIEF DESCRIPTION OF THE DRAWINGS

FIG. 1 schematically illustrates a conventional free-free workpiece of a Rosen-type piezoelectric transformer together with the internal vibration wave distribution thereof.

FIGS. 2A, 2B and 2C illustrate variants of piezoelectric transformers including a third-order longitudinal-mode device, an alternately-poled device and a center-drive half-lambda-mode device respectively.

FIGS. 3A and 3B respectively illustrate the symmetrical displacement field in a piezoelectric plate.

FIGS. 4A and 4B respectively illustrate multi-layer Rosen and multi-layer surface-to-surface type of piezoelectric transformers optimized in accordance with the teaching of the present invention.

FIG. 5A illustrates underlying concept for operation control schemes of the present invention including variable-frequency (VFC), pulse-width modulation (PWM) and self-resonance.

FIG. 5B schematically illustrates a piezoelectric transformer with effective surface electrodes for the actuator and sensor to match the mode-two strain field.

FIG. 6 schematically illustrates a self-resonance circuit for a piezoelectric transformer with positive feedback from a feedback node.

FIG. 7 schematically illustrates a Rosen-type piezoelectric transformer in a self-resonance circuit and operating in the second mode.

FIG. 8 shows the measured transfer function of the feedback sensor of FIG. 7 at selected locations.

FIG. 9 schematically illustrates a center-drive piezoelectric transformer in a self-resonance circuit and operating in the first mode.

FIG. 10 shows the measured transfer function of the feedback sensor of FIG. 9 at selected locations.

FIGS. 11A and 11B schematically illustrate multi-layer piezoelectric transformers operating in the second and the first mode respectively and with various feedback sensors.

FIGS. 12A and 12B show the transfer function of a Rosen-type piezoelectric transformer with a dimension of 44 by 6.5 by 2.2 mm (length, width and thickness) and FIGS. 12C and 12D that with a dimension of 40 by 5 by 2 mm.

FIG. 13 is a block diagram schematically outlining a prior art power supply system based on a traditional piezoelectric transformer.

FIG. 14 is a block diagram schematically outlining a power supply system in accordance with an optimal piezoelectric transformer of the present invention.

### DETAILED DESCRIPTION OF THE PREFERRED EMBODIMENTS

The governing equations of a piezoelectric solid in tensor notations are

T_{ij, j}=rüᵢ, (1a)

D_{j,j}=0, (1b)

where u is the displacement field, T and D are respectively stress and electric displacement, r is the density, and ij=1˜3. Body forces and the free charge densities are not included in EQS. (1a) and (1b) since only longitudinal vibration is considered. EQ. (1b) means that no free charge exists in the block of piezoelectric material. Note that the governing equations of a piezoelectric solid are PDE's instead of the ordinary differential equations (ODE) traditionally employed for the analyses based on the theory of equivalent circuits. This represents the nature limitations of the traditional piezoelectric transformers, since they can never know the spatial characteristics and cannot reach the optimal operating conditions.

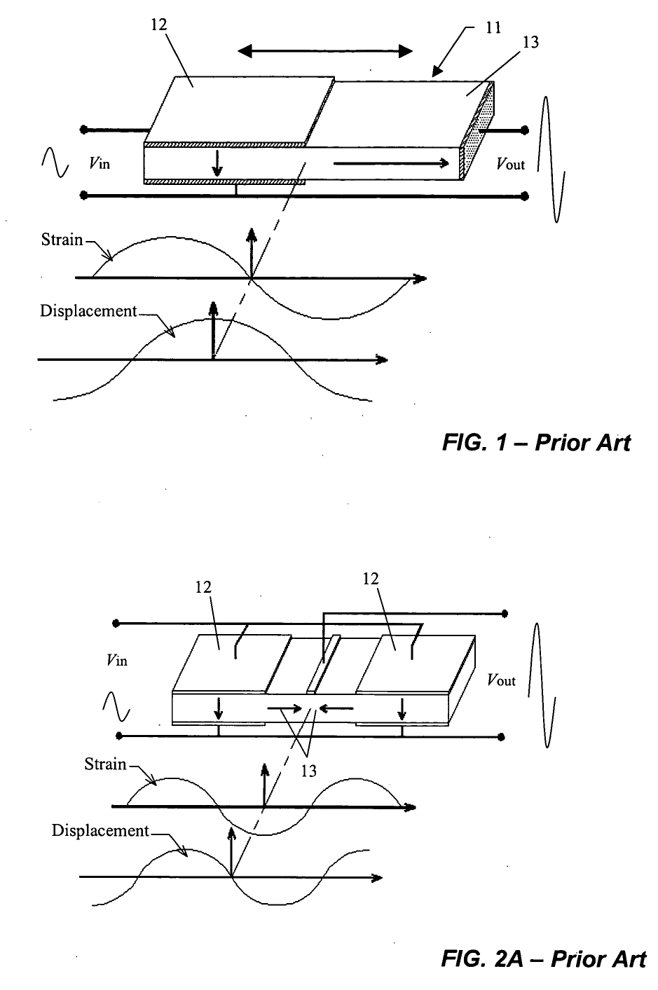

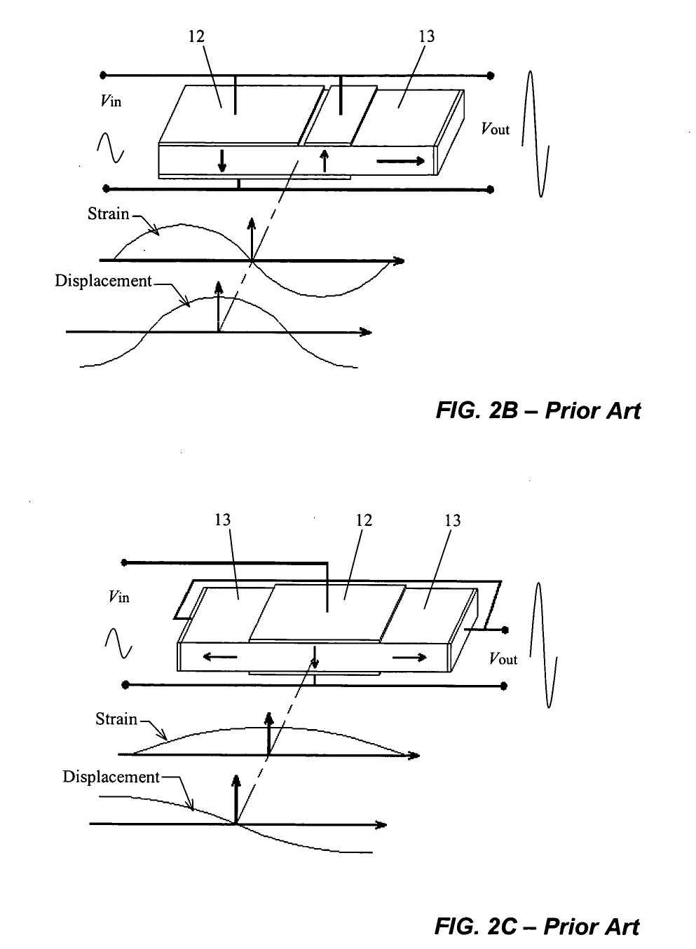

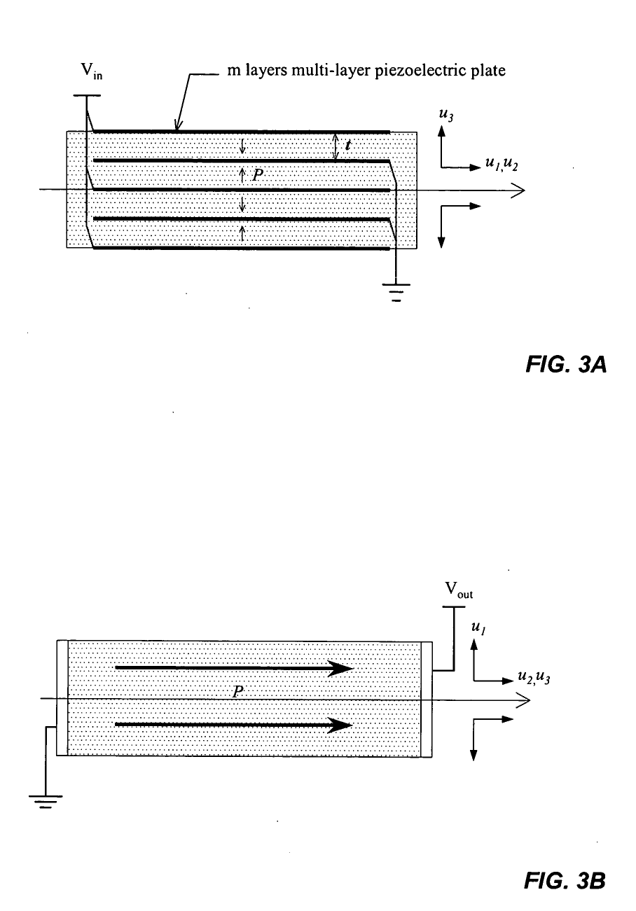

As are illustrated in FIGS. 1 and 2A, 2B and 2C, piezoelectric transformers are structures comprising of one or several actuators and sensors, which is operated at a specific resonant frequency of the adjoined structure. FIGS. 1 and 2A, 2B and 2C show that two different poling directions are present in a piezoelectric transformer. FIGS. 3A and 3B respectively represent the symmetrical displacement field of the piezoelectric plates with polarizations pointing along the thickness and the lateral directions, which are respectively similar to the actuator and sensor of a Rosen type piezoelectric transformer, as is illustrated in FIG. 1.

Since a piezoelectric transformer is a slender free-free plate that operates in its longitudinal resonance mode, it can be considered as a one-dimensional structure. This is assuming that the length of the piezoelectric plate is relatively much longer compared to the width thereof. Thickness of the electrodes are also much smaller than that of the bulk plate so that vibration wavelength in the structure along the longitudinal direction is not be significantly influenced by the boundaries along the width direction.

In accordance with the above considerations, the reduced governing equations and constitutive equations for the actuator and the sensor shown in FIGS. 3A and 3B become

c₁₁^{E}ũ_{1,11}−e₃₁mV₃ⁱⁿ=ρ\ddot{\tilde{u}}₁, (2a)

$$\begin{matrix}\{ \begin{matrix}{\tilde{T}}_{1} = {c}_{11}^{E} {\tilde{u}}_{1 , 1} - {me}_{31} ( {V}_{3} ) \\ mt {\tilde{D}}_{3} = {e}_{31} {\tilde{u}}_{1 , 1} + m {ϵ}_{33}^{s} ( {V}_{3} )\end{matrix} , \\ and & ( 2 b ) \\ ( {c}_{33}^{E} + \frac{{e}_{33}^{2}}{{ϵ}_{33}^{s}} ) {\tilde{u}}_{3 , 33} = ρ {\tilde{\ddot{u}}}_{3} , & ( 3 a ) \\ \{ \begin{matrix}{\tilde{T}}_{3} = {c}_{33}^{E} {\tilde{u}}_{3 , 3} - {e}_{33} ( {\tilde{E}}_{3} ) \\ {\tilde{D}}_{3} = {e}_{33} {\tilde{u}}_{3 , 3} + {ϵ}_{33}^{s} ( {\tilde{E}}_{3} )\end{matrix} . & ( 3 b )\end{matrix}$$

These are the governing equations for the actuator and the sensor of a one-dimensional piezoelectric plate respectively.

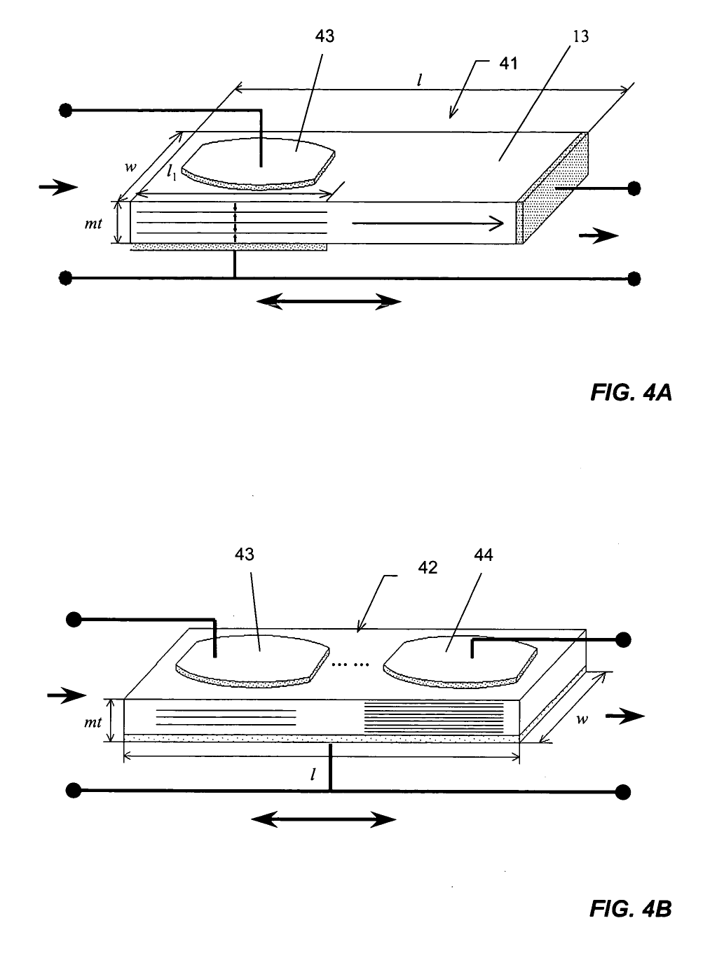

FIGS. 4A and 4B respectively illustrate two, namely, multi-layer Rosen 41 and multi-layer surface-to-surface 42, type of piezoelectric transformers optimized in accordance with the teaching of the present invention, in which multi-layer actuator 43 and sensor 44 are considered. Note that Rosen-type piezoelectric transformer is an adjoining piezoelectric plate with different actuator and sensor polarization. This does not imply that sensor and actuator were made separately and then connected together. Various configurations can be implemented with ease by the implementation of different poling directions within a single piezoelectric plate. In accordance with the present invention, distributed actuator and/or sensor on the piezoelectric transformer workpiece can be designed for matched mechanical stress/strain.

This additional freedom of design in accordance with the teaching of the present invention provides for the optimization of the electromechanical energy conversion in the spatial domain. Bulk motion of a piezoelectric transformer schematically illustrated in FIGS. 4A and 4B is in the in-plane longitudinal mode and analytical approximation is possible utilizing a one-dimensional plate model. Typical materials used to manufacture piezoelectric transformers are based on lead, zirconate and titanate (PZT), which possess a class 6 mm symmetry crystal system. Since a piezoelectric transformer operates with longitudinal vibrations in a slender piezoelectric solid body, only stresses in the orthogonal direction are generated when the electric field is applied in the x₃ direction.

General Solutions for Piezoelectric Transformer

According to the one-dimensional governing equations of a piezoelectric plate shown in EQS. (2) and (3), transfer functions of a Rosen type and a surface-to-surface piezoelectric transformer in a partial differential equation system constructed for the piezoelectric solids as in EQ. (1) are, respectively,

$$\begin{matrix}\frac{{V}_{3 s}^{out}}{{V}_{3 a}^{i n}} = {\sum }_{i = 1}^{∞} \frac{jω {Z}_{L} {C}_{s}}{1 + jω {Z}_{L} {C}_{s}} \frac{\begin{matrix}m \frac{w}{t} \frac{{e}_{31}^{2}}{ρ {C}_{s}} {\int }_{0}^{1} {{A}^{′}}_{a} ( x ) {φ}_{i} ( x ) ⅆ x \\ [ {φ}_{i} ( {l}_{p} ) - {φ}_{i} ( {l}_{1} ) ]\end{matrix}}{\begin{matrix}\begin{matrix}( {ω}_{i}^{2} + 2 ζ ( jω ) {ω}_{i} - {ω}^{2} ) - \\ \frac{1}{( {l}_{p} - {l}_{1} )} \frac{1}{1 + jω {Z}_{L} {ϵ}_{33}^{s}} \frac{{e}_{33}^{2}}{ρ {C}_{s}}\end{matrix} \\ {φ}_{i} ( {l}_{p} ) [ {φ}_{i} ( {l}_{p} ) - {φ}_{i} ( {l}_{1} ) ]\end{matrix}} \\ and & ( 4 a ) \\ \frac{{V}_{3 s}^{out}}{{V}_{3 a}^{i n}} = {\sum }_{i = 1}^{∞} \frac{jω {Z}_{L} {C}_{s}}{1 + jω {Z}_{L} {C}_{s}} \frac{{m}_{a} \frac{w}{{t}_{s}} \frac{{e}_{31}^{2}}{ρ {C}_{s}} {A}_{1} {S}_{2}}{\begin{matrix}( {ω}_{i}^{2} + 2 ζ ( jω ) {ω}_{i} - {ω}^{2} ) - \\ {m}_{s} \frac{w}{{t}_{s}} \frac{jω {Z}_{L} {C}_{s}}{1 + jω {Z}_{L} {C}_{s}} \frac{{e}_{31}^{2}}{ρ {C}_{s}} {S}_{1} {S}_{2}\end{matrix}} & ( 4 b )\end{matrix}$$

where V₃ₛ^{out}, and V₃ⁱⁿ are input and output voltages respectively, ωᵢ is the i^{th} resonance frequency of the piezoelectric transformer, Cₛ and Z_{L} are the output static capacitance and load impedance respectively, ζ and ρ are the damping ratio and density respectively, and φᵢ(x) is the mode shape of the i^{th} mode.

In EQ. 4(a), lₚ and lₗ are respectively the lengths of the overall piezoelectric transformer and actuator, Aₐ(x) is the shape function of the actuator, m represents the total number of layers in the actuator, and w and t are respectively the width and thickness of each layer of the Rosen-type piezoelectric transformer. In EQ. (4b), w and tₛ are respectively the width and thickness of each layer of the surface-to-surface piezoelectric transformer, mₐ and mₛ represent the number of layers in actuator and sensor respectively, and

A₁=∫₀¹A′ₐ(x)φᵢ(x)dx, A₂=∫₀¹Aₐ(x)φ′ᵢ(x)dx, (5a,b)

S₁=∫₀¹A′ₐ(x)φᵢ(x)dx, S₂=∫₀¹Sₐ(x)φ′ᵢ(x)dx, (5c,d)

where Aₐ(x) and Sₐ(x) are the shape of the actuator and sensors respectively.

On the other hand, the input impedance derived from the partial differential equations shown in EQ (1) for Rosen-type and surface-to-surface piezoelectric transformers are, respectively,

$$\begin{matrix}{Z}_{e} = {\sum }_{i = 1}^{∞} \frac{- 1}{jω {c}_{a}} \frac{\begin{matrix}\begin{matrix}( {ω}_{i}^{2} + 2 ζ ( jω ) {ω}_{i} - {ω}^{2} ) - \\ \frac{1}{( {l}_{p} - {l}_{1} )} \frac{1}{1 + jω {Z}_{L} {C}_{s}} \frac{{e}_{33}^{2}}{ρ {ϵ}_{33}^{s}}\end{matrix} \\ {φ}_{i} ( {l}_{p} ) [ {φ}_{i} ( {l}_{p} ) - {φ}_{i} ( {l}_{1} ) ]\end{matrix}}{\begin{matrix}\begin{matrix}( {{ω}^{′}}_{i}^{2} + 2 ζ ( jω ) {{ω}^{′}}_{i} - {ω}^{2} ) - \\ \frac{1}{( {l}_{p} - {l}_{1} )} \frac{1}{1 + jω {Z}_{L} {C}_{s}} \frac{{e}_{33}^{2}}{ρ {ϵ}_{33}^{s}}\end{matrix} \\ {φ}_{i} ( {l}_{p} ) [ {φ}_{i} ( {l}_{p} ) - {φ}_{i} ( {l}_{1} ) ]\end{matrix}} , \\ where & ( 6 a ) \\ {{ω}^{′}}_{i}^{2} = {ω}_{i}^{2} - m \frac{w}{t} \frac{{e}_{31}^{2}}{ρ {C}_{a}} {\int }_{0}^{1} {{A}^{′}}_{a} ( x ) {φ}_{i} ( x ) ⅆ x {\int }_{0}^{1} {A}_{a} ( x ) {{φ}^{′}}_{i} ( x ) ⅆ x , \\ and & ( 6 b ) \\ {Z}_{e} = {\sum }_{i = 1}^{∞} \frac{- 1}{jω {c}_{a}} \frac{\begin{matrix}( {ω}_{i}^{2} + 2 ζ ( jω ) {ω}_{i} - {ω}^{2} ) - \\ {m}_{s} \frac{w}{{t}_{s}} \frac{jω {Z}_{L} {C}_{s}}{1 + jω {Z}_{L} {C}_{s}} \frac{{e}_{31}^{2}}{ρ {C}_{s}} {S}_{1} {S}_{2}\end{matrix}}{\begin{matrix}( {ω}_{i}^{′2} + 2 ζ ( jω ) {ω}_{i}^{′} - {ω}^{2} ) - \\ {m}_{s} \frac{w}{{t}_{s}} \frac{jω {Z}_{L} {C}_{s}}{1 + jω {Z}_{L} {C}_{s}} \frac{{e}_{31}^{2}}{ρ {C}_{s}} {S}_{1} {S}_{2}\end{matrix}} , \\ where & ( 7 a ) \\ {ω}_{i}^{′2} = {ω}_{i}^{2} - {m}_{a} \frac{w}{{t}_{a}} \frac{{e}_{31} {e}_{31}}{ρ {C}_{a}} {A}_{1} {A}_{2} . & ( 7 b )\end{matrix}$$

From these equations it can be seen that shape is itself a function that can be used for the matching of the mechanical characteristic in the system of a piezoelectric transformer. Both the transfer functions shown in EQS. (4a) and (4b), as well as the input impedance of the piezoelectric transform shown in EQS. (6a) and (7a), are themselves functions, or parameters, of the shape of the actuator and sensor (Aₐ(x) and Sₐ(x)), the load impedance (Zᵢ), the output static capacitance (Cₛ), the number of the actuator and sensor layers (m/mₐ and mₛ) and the geometry and material property of the piezoelectric transformer.(w, t, lₗ, lₚ)

Optimization of the Surface-to-Surface Piezoelectric Transformer

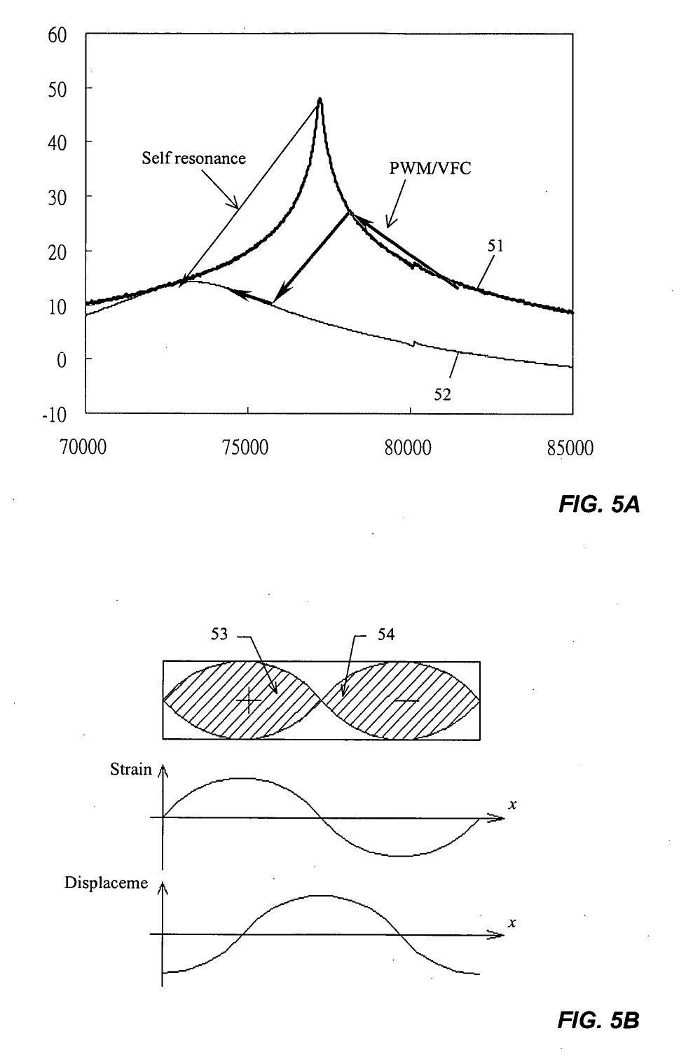

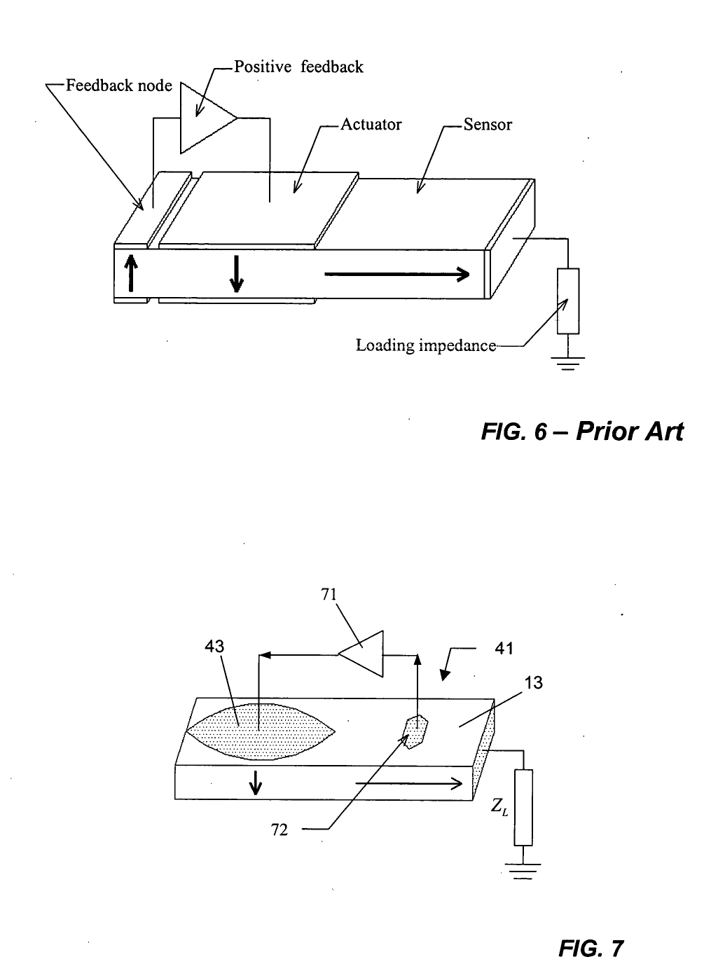

Unlike a typical two-node device employing sensor and actuator nodes, a piezoelectric transformer functioning as a power transfer device is a three-node device requiring a different interface circuit. Both the resonance frequency and step-up ratio of the piezoelectric transformer device depends to a great extend on load conditions. Resonance frequency of the piezoelectric transformer changes from high frequency to low as the load impedance also changes from high to low. A CCFL is substantially an open-circuit load to a power source before turned on and a load with impedance of hundreds of k-ohms after on. In an application wherein a CCFL is the load to a piezoelectric transformer, the voltage step-up ratio of the device drops from roughly 2,500 to 5 as the CCFL turns from off (curve 51) to on (curve 52), a reduction of one to two orders of magnitude. See FIG. 5A.

This phenomenon that the step-up ratio of a piezoelectric transformer changes with the load status becomes an advantageous characteristics that makes it substantially the best possible driving device for CCFL. Various previous efforts had concentrated on the maximization of both power injection into and extraction out of a piezoelectric transformer device—the pursuit of maximum transformer efficiency for devices of specific sizes. By contrast, and in accordance with the teaching of the present invention, it can be shown that power transfer optimization in a piezoelectric transformer device is not determined solely in terms of the size factor. It can be shown that optimization of a piezoelectric transformer aimed at the power transfer efficiency is achievable. It is achievable by matching the electrical impedance of the input to that of the output and/or by matching the modal strain of the structural resonance of the device to the shape of the electrodes on the device workpiece.

Maximum Power Transfer by Impedance Match

Output impedance of a piezoelectric transformer can be determined solely in terms of the static capacitance of the sensor, i.e., the output section. Considering a case in which the output impedance |1/jωCₛ| equals to the load impedance Z_{L} under resonance frequency. This is a situation in which the transfer of output power by the piezoelectric transformer is optimized, or, maximized. Under this condition, input impedance and system transfer function of a surface-to-surface piezoelectric transformer can be derived from EQS. (4b) and (7a):

$$\begin{matrix}{Z}_{e} = {\sum }_{i = 1}^{∞} \frac{- 1}{jω {c}_{a}} \frac{( {{ω}^{\overline{\_}}}_{i}^{2} + 2 {ζ}^{′} ( jω ) {{ω}^{\overline{\_}}}_{i} - {ω}^{2} )}{( {{{ω}^{\overline{\_}}}^{′}}_{i}^{2} + 2 {ζ}^{′} ( jω ) {{ω}^{\overline{\_}}}_{i}^{′} - {ω}^{2} )} , & ( 8 a ) \\ \frac{{V}_{3 s}^{out}}{{V}_{3 a}^{i n}} = {\sum }_{i = 1}^{∞} \frac{jω {Z}_{L} {C}_{s}}{1 + jω {Z}_{L} {C}_{s}} \frac{{m}_{a} \frac{w}{{t}_{s}} \frac{{e}_{31}^{2}}{ρ {C}_{s}} {A}_{1} {S}_{2}}{( {{ω}^{\overline{\_}}}_{i}^{2} + 2 {ζ}^{′} ( jω ) {{ω}^{\overline{\_}}}_{i} - {ω}^{2} )} , \\ wherein & ( 8 b ) \\ {{ω}^{\overline{\_}}}_{i}^{2} = {ω}_{i}^{2} - {m}_{s} \frac{1}{2} \frac{w}{{t}_{s}} \frac{{e}_{31}^{2}}{ρ {C}_{s}} {S}_{1} {S}_{2} , & ( 9 a ) \\ {{ω}^{\overline{\_}}}_{i}^{′2} = {ω}_{i}^{2} - {m}_{a} \frac{w}{{t}_{a}} \frac{{e}_{31}^{2}}{ρ {C}_{a}} {A}_{1} A - {m}_{s} \frac{1}{2} \frac{w}{{t}_{s}} \frac{{e}_{31}^{2}}{ρ {C}_{s}} {S}_{1} {S}_{2} , & ( 9 b ) \\ 2 {ζ}^{′} ( jω ) {{ω}^{\overline{\_}}}_{i} = 2 ζ ( jω ) {ω}_{i} - {m}_{s} \frac{j}{2} \frac{w}{{t}_{s}} \frac{{e}_{31}^{2}}{ρ {C}_{s}} {S}_{1} {S}_{2} . & ( 9 c )\end{matrix}$$

It is clear from EQ. (9) that a high-pass filter transferring maximum power raises both its resonance frequency and damping ratio. This implies that optimal operating condition of a piezoelectric transformer depends both on the mechanical and the electrical characteristics thereof. Transfer function under this condition is determined also by the additional frequency response characteristics of the high-pass filter at the output electrode, and the reductions of the quality factor and resonance frequency are functions of both the shape and location of the sensor of the device.

Traditional approaches of employing equivalent circuits for the modeling of the behavior of a piezoelectric transformer were unable to encompass this condition in entirety as the information representative of the spatial characteristics was not included into consideration. Mechanically, a piezoelectric transformer is electrically and mechanically a fully-coupled system and its mechanical motion is determined both by the mechanical and electrical boundary conditions. On the other hand, the equivalent electrical property is also determined both by the mechanical and electrical boundary conditions. Thus, variations in the load conditions influence the input impedance and the transfer function of the device. The reduction of both the quality factor and the resonance frequency means that power sink into the load makes an equivalent structural damper in the device. Under maximum power transfer at operating resonance frequency, the high-pass filter introduces a 45° phase-lead into the transfer function as the output impedance |1/jωCₛ| becomes equal to Z_{L} in EQ. (23).

Further, the step-up ratio becomes effectively cancealled by this high-pass filter since the load impedance is much smaller than the output impedance of the piezoelectric transformer. In other words, if the load impedance is much smaller than the output impedance, the desired step-up ratio cannot be fully available. This is because that the step-up ratio becomes “rolled off” by the effective high-pass filter introduced due to the load impedance Z_{L} and the output static capacitance Cₛ.

Since the mechanical quality factor of the piezoelectric transformer is substantially up to two thousand, the second term in EQ. (13-10c) becomes much larger than the first. Transfer function of the surface-to-surface piezoelectric transformer operating at the resonance frequency can then be expressed in an approximation as

$$\vert \frac{{V}_{3 s}^{out}}{{V}_{3 a}^{i n}} \vert = \vert \sqrt{2} \frac{{m}_{a} {A}_{1}}{{m}_{s} {S}_{1}} \vert . \qquad ( 13 \text{-} 11 )$$

Note that the ratio mₐ/mₛ and the shapes of the actuator and sensor together determine the step-up ratio of the piezoelectric transformer. As the shapes of the sensor and actuator are selected according to the principle of the concept of modal sensor and actuator, step-up ratio can only be dependent on the ratio mₐ/mₛ. Desired step-up ratio of a piezoelectric transformer can thus be set with ease by the utilization of a multi-layer manufacturing process.

For a single-layer piezoelectric transformer where mₐ/mₛ equals to one, the step-up ratio is fixed to |\sqrt{2}A₁/S₁51 . Impedance matching for a piezoelectric transformer for maximum power transfer is achievable by the matching of the output impedance to that of the load. This can be done by adjustment of the output static capacitance by the selection of the total number of sensor layers. Correspondingly, the total number of actuator layers is determined according to the desired step-up ratio as per the descriptions above. It should be noted that the capacitance of the actuator section is typically set to be matched with the output impedance of the driving electronics, which is typically at 50Ω for standard signal electronics and is set to be close to zero for power electronic applications. In this manner, the optimal electrical condition of a piezoelectric transformer is set to that for maximum power transfer.

In accordance with the above-described procedure of analysis, it is clear that this inventive concept of design is also applicable to the Rosen-type piezoelectric transformer, whose transfer function and input impedance are shown in EQS. 4(a) and 6(a) respectively. The only difference being that the output section of a Rosen-type piezoelectric transformer does not constitute a shape function at the sensor. Thus, the only means for achieving load impedance matching is via the modification of the geometry of the output section. In other words, output static capacitance can be modified to achieve maximum power transfer.

Optimizing Sensors and Actuators by Matching Modal Strain

Modal sensors and actuators were first introduced in the late 80's (Lee, 1987; Lee and Moon, 1900) and the fundamental design concept was to match the modal strain in a specific mode by shaping the effective surface electrode to handle the spillover in the flexible structural control. Since the shaped electrode in EQS. (4, 6 and 7) offers a weighting function to the eigenfunction φᵢ(x), orthogonality condition of eigenfunctions can be adopted for the design of modal sensors and actuators. More specifically, since

∫₀¹φᵢ(x)φⱼ(x)dx=1, for i=j, (13-12)

and the expression equals to zero if i≠j, and the setting of A′ₐ(x)=φᵢ(x) and Sₛ(x)=φ′ᵢ(x) for A₁ and S₂ in EQ. (5) leads to the conclusion that only the i^{th} resonance mode can be actuated and sensed by the piezoelectric transformer. Under this condition, a piezoelectric transformer behaves like a single-mode resonance tank, which has only one resonance frequency.

Provided this condition is true, the piezoelectric transformer can be described fully by an ordinary differential equation. That is, based on the concept of modal sensor and actuator, a spatially-dependent equivalent circuit can be adopted for the study of the electrical behavior of the piezoelectric transformer, which, in this case, is similar to the traditional approach. It is comprehensible that with proper application of the equivalent circuit theory to the design of a piezoelectric transformer, the interface circuits necessary for the operation of the piezoelectric transformer at its fullest operating regime becomes realizable.

FIG. 5B illustrates the schematics of a piezoelectric transformer with an effective surface electrode of the actuator section 53 matched to the left half period of the mode-two strain field and that of the sensor section 54 matched in the right half. Since the piezoelectric transformer operates on the chosen resonance frequency, strain distribution across the bulk of the piezoelectric transformer is matched to the modal strain field in the mode the device operates in.

Specifically, shaping of the actuator electrode for the matching to the modal strain distribution leads to a situation in which the flow of electrical energy is only spread in the specific selected mode. On the other hand, a shaped modal sensor only sinks the energy generated in this mode. An optimized coupling for an energy transfer across the piezoelectric bulk with internal mechanical motion and the electrical interface circuits can then become achievable. In summary, a piezoelectric transformer optimized for maximum power transfer encompasses two elements: First, load impedance of the device is matched to a design output impedance and, secondly, the concept of the modal sensor and actuator is adopted to implement the matching of the desired modal strain distribution.

Feedback Sensor Design for Piezoelectric Transformers

Based on the same analytical reasoning of the partial differential equations in EQS. (2) and (3), the governing equation of a multi-input multi-output (MIMO) piezoelectric transformer can be similarly derived. Characteristics of each sensor and actuator are the same as that of a single-input single-output (SISO) piezoelectric transformer. A sensor performs two functions. First, it serves as the power transferring section and, secondly, it provides to the control loop a feedback representative of the structural information. Feedback sensors do not actually consume energy, rather, substantially only structural information is involved and considered. Signal processing interface circuit must also be included into consideration since part of the transferred energy can be drawn from this feedback sensor. In other words, design requirement of the interface circuit for this feedback sensor is that it does not drain power while monitoring structural information in the piezoelectric transformer.

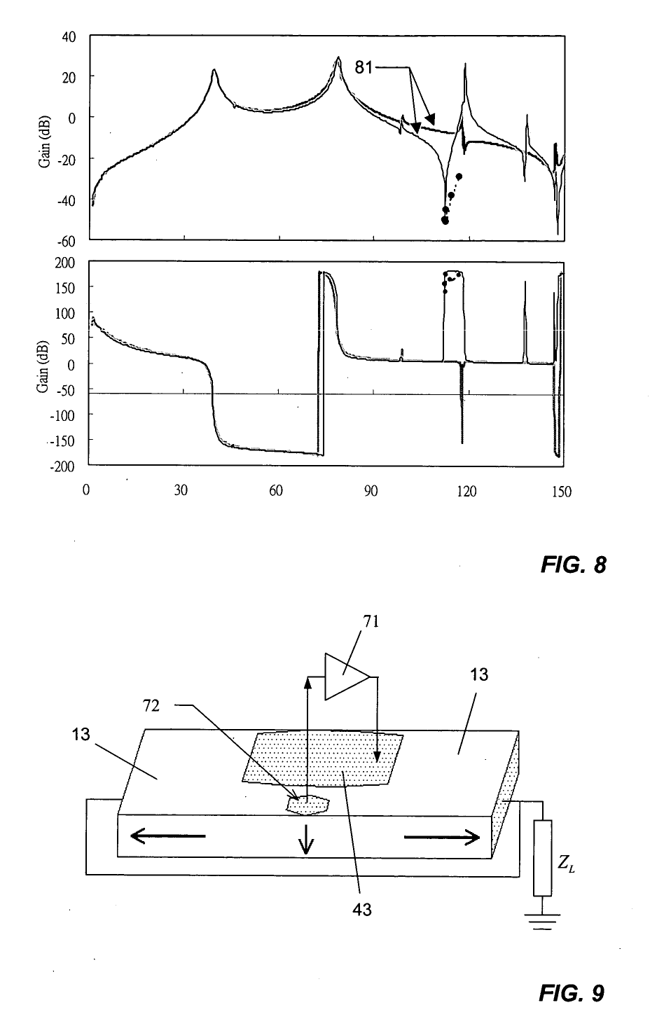

The idea of the use of feedback sensors had been known. However, inclusion of the spatial information into the analytical considerations of piezoelectric transformers had not been proposed. Consider the case in which the sensor Sₐ(x) shown in the derived governing equation of the surface-to-surface piezoelectric transformer (EQ. 4(a)) is used as a feedback sensor. It can be shown that the feedback is a function of its spatial distribution and location. This can be interpreted experimentally by moving the feedback sensor 72 of the piezoelectric transformer 41 toward the actuator 43 (shown in FIG. 7) along the longitudinal direction. Transfer function measured in the experiment is shown in FIG. 8. It is obvious from FIG. 8 that the transfer function 81 of the feedback sensor can be tailored utilizing its own spatial characteristic. A self-resonance piezoelectric transformer can thus be easily implemented in accordance with the present invention without the undesirable increase of component counts. A positive feedback 71 is indicative of a self-resonance circuit in FIG. 7.

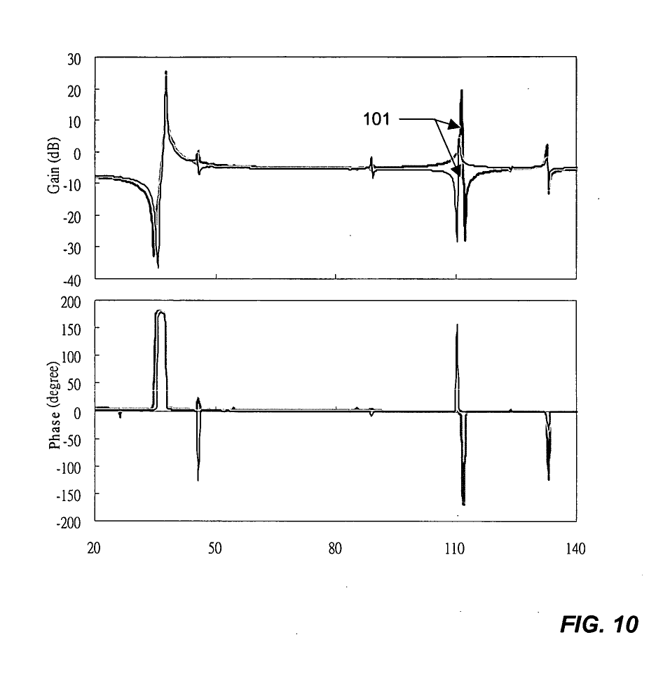

For piezoelectric transformers operating in the first mode, such as the system shown in FIG. 9, it is known from experimental results 101 of a side-by-side piezoelectric transformer (shown in FIG. 10). FIG. 9 schematically outlines the circuit of a central-drive piezoelectric transformer operating in the second and driven mode under self-resonance. With the introduction of a positive feedback circuit 71, self-resonance in a piezoelectric transformer operating in first mode can be implemented.

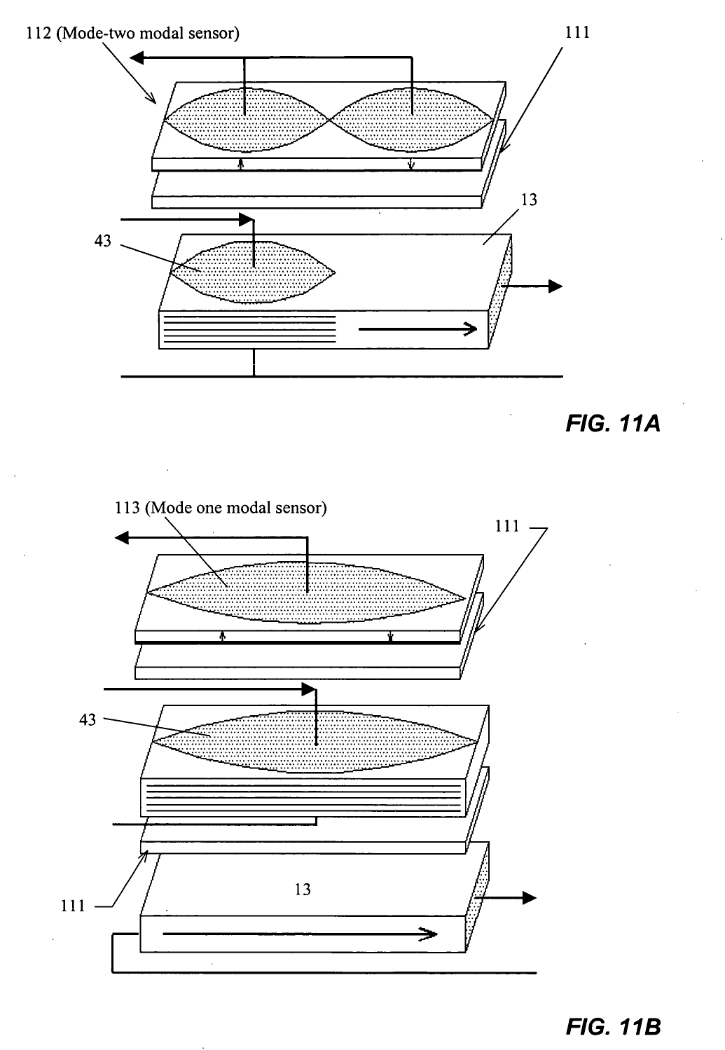

All of these design concepts hold for multi-layer piezoelectric transformers operating in the first and second modes. Multi-layer configurations also provide another degree of freedom for the design of feedback nodes (refer to FIGS. 11A and 11B). A feedback node 112/113 can be implemented within another layer in a multi-layer piezoelectric transformer. If the piezoelectric material layer 111 in between is not polarized, the feedback node can be floated mechanically. On the other hand, fill mode-one 113 and mode-two 112 feedback nodes can be implemented on the piezoelectric transformer operating in the first and the second mode respectively to pick up the operating resonance frequency for feedback. As only one of the operating resonance frequencies is picked up from a modal sensor, the pole-zero alternating phenomenon would not be substantial. FIGS. 11A and 11B schematically illustrate multi-layer piezoelectric transformers operating in the second and the first mode respectively.

Note that the multi-layer piezoelectric transformer illustrated in FIG. 7 is a piezoelectric transformer with isolated actuator, sensor and feedback nodes. It should be noticed that the major concern of the self-resonance circuit is the frequency response of the feedback node, in particular the phase distribution. Since the phase can be handled properly, any orientation of the piezoelectric transformer can be applicable for the implementation of the concept of self-resonance.

Arguably a phase compensation circuit can be added to the feedback circuit for the control of the desired phase distribution such that a feedback node is not needed. This is true conceptually. However, it will never be applicable in any of today's commercialized piezoelectric transformer modules. There are two reasons for this. First, the resonance frequency of a piezoelectric transformer is spaced apart in the octaves while filtering effect of an electronic filter is in decades. High-order electrical filters are needed to make electronic filter viable. However, phase lag associated with the added electronic filter inevitably messes up the phase of the feedback node. Further, the extra compensation circuit in the feedback circuit renders mass production more complicated and costly. Since the signal processing had been handled with spatially-distributed feedback nodes, the feedback circuit thus becomes relatively simple. Since the mass production of the feedback node discussed above involves no more than a screen-printing process, the cost of the piezoelectric transformer will not be increased by the introduction of the feedback node.

Shape Effect of Piezoelectric Transformers

All of the above-described examples are related to ones with longitudinal vibrations of the piezoelectric transformer. However, piezoelectric transformers are in fact slender plates, they must be considered as finite plates in high frequency or short wavelength. Width and thickness resonance modes appear in the range of hundreds or even millions of hertz for a piezoelectric transformer with a dimension of 44 mm long by 6.5 m wide by 22 mm thick operating at some point around 80 kHz. Although reportedly distributed sensor and actuator, modal actuator/sensor and symmetric APROPOS device were all able to provide spatial filtering effect to a piezoelectric transformer, they, however, cannot operate in vibration modes other than to deal with the longitudinal vibrations. This was because they were designed utilizing the conventional one-dimensional model. These high frequency resonance modes introduce high frequency harmonics to the output and result into the substantial reduction of life expectancy of the load, such as a CCFL, that is driven by the transformer.

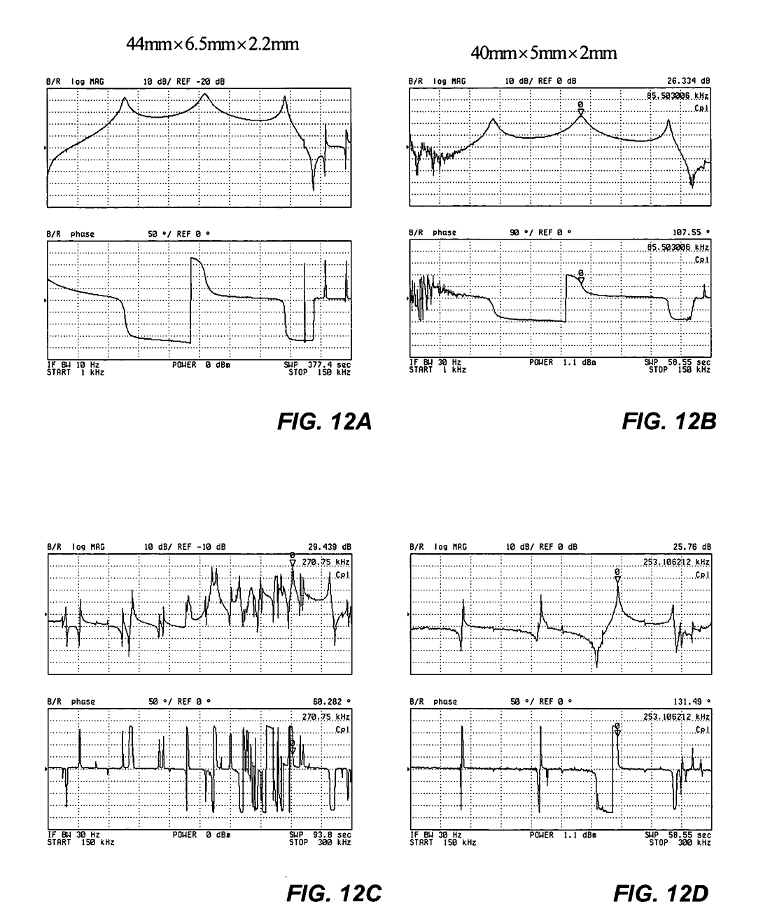

It is known that if the wavelengths of the longitudinal, width and thickness modes of a plate are proportioned, the resonance modes with identical wavelength will occur at the same frequency range (Graff, 1975). This shape effect can be seen from the frequency responses of the 44 mm long by 6.5 mm wide by 22 mm thick and 40 mm long by 5 mm wide by 2 mm thick piezoelectric transformers shown in FIGS. 12A-12D. Note that the 40 mm×5 mm×2 mm piezoelectric transformer has its shape is parameters in a direct ratio had fewer resonance modes in high frequency. The idea is to utilize the degeneracy to simplify the transfer function as multiple modes would correspond to a single frequency in this situation. That is, high-frequency harmonics can be reduced due to shape effect of the mechanical geometry.

Scheme for Construction of Optimized Piezoelectric Transformers

In constructing an optimized piezoelectric transformer, in accordance with the teachings of the present invention, the detailed scheme is as follows:

A. Determine transformer voltage step-up/down ratio. This requires the consideration for application requirements.

B. Determine transformer workpiece operating frequency range and load-driving capability.

C. Select type of piezoelectric transformer most suitable for determined ratio and frequency.

D. Settle piezoelectric workpiece geometrical dimensions for the determined ratio.

E. Find optimal operating condition of the settled piezoelectric workpiece. This involves the matching of load impedance and the matching of modal strain distribution.

F. Configure specific sensor geometry and layer number of the multi-layer workpiece to match the required load impedance.

G. Determine actuator layer number of the multi-layer workpiece to match the required voltage step-up/down ratio.

H. Select appropriate circuit topology for the electric circuit subsystem for convergence to the desired optimal operating condition of the transformer system. Various circuit topologies are available for selection.

I. Utilize additional workpiece electrode(s) to further simplify circuitry (reducing component count). Various electrodes are available other than Feedback electrode.

Generalized Scheme for Construction of Optimized Piezoelectric Transformer

In constructing an optimized piezoelectric transformer, in accordance with the teachings of the present invention, a generalized scheme is as follows:

A. Shape up the piezoelectric workpiece in accordance with application requirements:

Actuator layer number, which is determined by voltage step-up/down ratio.

Sensor geometrical shape and layer number, which is determined by the required load impedance.

Appropriate workpiece operating frequency range and reasonable load-driving capability.

Type of workpiece, including Rosen type, surface-to-surface type, etc.

B. Find optimal operating condition of selected piezoelectric workpiece

Resolution into optimization by matching load impedance and matching modal strain distribution.

C. Select appropriate circuit topology for electric circuit subsystem (for convergence to the desired optimal operating condition of the transformer system)

D. Apply additional workpiece electrode(s) to minimize circuit complexity (reducing component count).

Thus, in accordance with the teachings of the present invention, the underlying innovative concept employed for implementing the design and construction of an optimized piezoelectric transformer rests on the fact that a piezoelectric transformer device is a fully electrically- and mechanically-coupled system. For optimization, the piezoelectric workpiece of such a transformer needs to operate as a mechanical resonance device.

In accordance with the present invention, governing equations are mathematically established in a set of partial differential equations, upon which field equations can be derived. Based on the derived field equations, total frequency response characteristics of an analyzed piezoelectric transformer can be investigated fully. With both spatial and temporal dependencies of a piezoelectric transformer considered in its derived field equations, the concept of distributed sensor and actuator can be employed to arrive at an optimized piezoelectric transformer design.

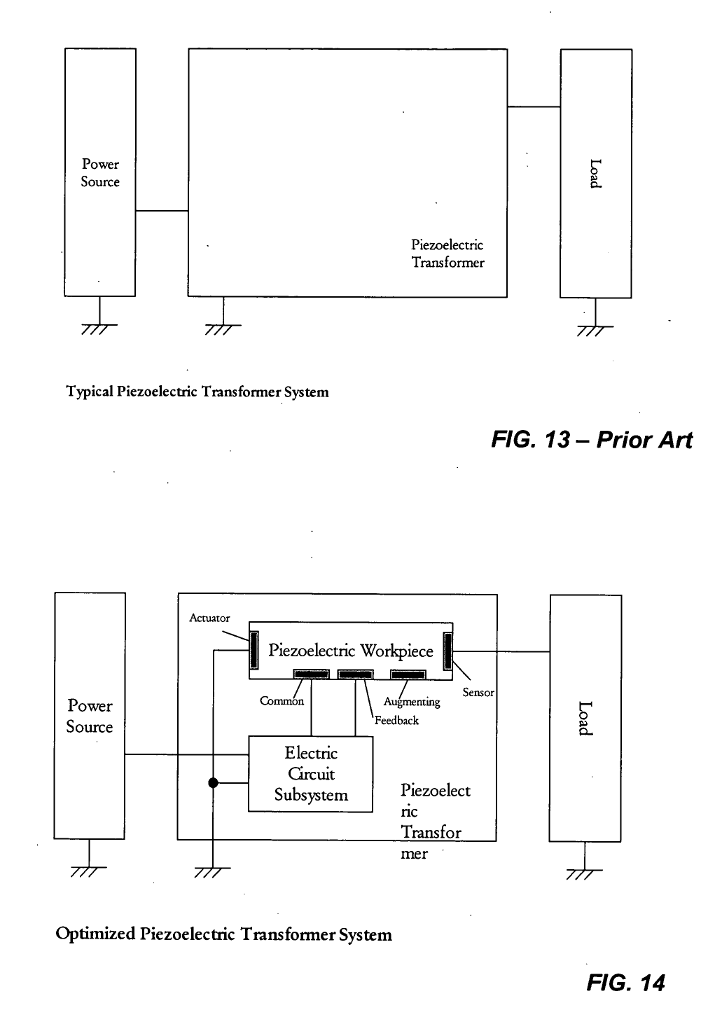

To optimize a piezoelectric transformer system, in accordance with the present invention, electric circuit subsystem coupled to the transformer workpiece is built to match the characteristic (both electrically and mechanically) of the workpiece. Use of a feedback node placed to the designed location on the surface of the workpiece minimizes the component counts of a self-resonant circuit subsystem implementation in such a piezoelectric transformer system. It has been demonstrated that the optimal operating condition of a piezoelectric transformer system is one in which impedance of the load is electrically matched to the driving transformer and, mechanically, the workpiece of the piezoelectric device itself is operating under modal strain. FIGS. 13 and 14 illustrate the difference between the present invention and traditional piezoelectric transformer-based power supply systems.

While the above is a fill description of the specific embodiments, various modifications, alternative constructions and equivalents may be used. Therefore, the above description and illustrations should not be taken as limiting the scope of the present invention which is defined by the appended claims.

What is claimed is:

1. A piezoelectric transformer apparatus for converting electrical input energy into electrical output energy for driving a load, said apparatus comprising
at least one actuator section having a modal-shaped electrode for optimized electrical-to-mechanical energy conversion for exciting mechanical vibration in said apparatus; and
at least one sensor section having a sensor electrode with the electrical impedance of output static capacitance thereof matched to impedance of said load for optimized conversion of the energy of said excited mechanical vibration into electrical energy for driving said load.

2. The piezoelectric transformer apparatus of claim 1 wherein said modal-shaped electrode of said at least one actuator section is a multi-layer actuator.

3. The piezoelectric transformer apparatus of claim 1 wherein said sensor electrode of said at least one sensor section is a multi-layer sensor.

4. The piezoelectric transformer apparatus of claim 3 wherein said multi-layer sensor matches said output static capacitance to the impedance of said load.

5. The piezoelectric transformer apparatus of claim 1 wherein said workpiece is a surface-to-surface piezoelectric transformer workpiece having a modal sensor for optimizing the mechanical-to-electrical energy conversion in the output stage of said apparatus.

6. The piezoelectric transformer apparatus of claim 1 wherein said workpiece has a geometrical dimension tailored for matching said output static capacitance to said impedance of said load.

7. The piezoelectric transformer apparatus of claim 1 wherein said at least one actuator and said at least one sensor are separated by an insulating layer.

8. The piezoelectric transformer apparatus of claim 2 wherein said multi-layer actuator of said workpiece is tailored for matching input impedance of said apparatus for optimized electrical energy conversion.

9. A piezoelectric transformer apparatus for converting electrical input energy into electrical output energy for driving a load, said apparatus comprising
at least one actuator section having a modal-shaped electrode for optimized electrical-to-mechanical energy conversion for exciting mechanical vibration in said apparatus;
at least one sensor section having a sensor electrode with the electrical impedance of output static capacitance thereof matched to impedance of said load for optimized conversion of the energy of said excited mechanical vibration into electrical energy for driving said load; and
at least one feedback sensor having a predetermined shape function and located at a predetermined location on the workpiece of said transformer for feedback of information of said conversion in said apparatus for optimization control of said conversion.

10. The piezoelectric transformer apparatus of claim 9 wherein said modal-shaped electrode of said at least one actuator section is a multi-layer actuator.

11. The piezoelectric transformer apparatus of claim 9 wherein said sensor electrode of said at least one sensor section is a multi-layer sensor.

12. The piezoelectric transformer apparatus of claim 9 wherein said workpiece provides a feedback information to said feedback sensor for the construction of a self-resonance circuit.

13. The piezoelectric transformer apparatus of claim 10 wherein said multi-layer actuator of said workpiece determines the step-up ratio of said apparatus.

14. The piezoelectric transformer apparatus of claim 11 wherein said multi-layer sensor of said workpiece determines the step-up ratio of said apparatus.

15. The piezoelectric transformer apparatus of claim 11 wherein said multi-layer sensor of said workpiece is tailored for matching the output static capacitance of said apparatus to the impedance of said load.

16. The piezoelectric transformer apparatus of claim 9 wherein said workpiece is a surface-to-surface piezoelectric transformer workpiece having a modal sensor for optimizing the mechanical-to-electrical energy conversion in the output stage of said apparatus.

17. The piezoelectric transformer apparatus of claim 9 wherein said workpiece has a geometrical dimension tailored for matching said output static capacitance to said impedance of said load.

18. The piezoelectric transformer apparatus of claim 9 wherein said actuator, said sensor, and said feedback sensor are separated by insulating layers.

19. The piezoelectric transformer apparatus of claim 9 wherein said multi-layer actuator of said workpiece is tailored for matching input impedance of said apparatus for optimized electrical energy conversion.

20. A piezoelectric transformer apparatus for converting electrical input energy into electrical output energy for driving a load, said apparatus comprising
at least one actuator section having a modal-shaped electrode for optimized electrical-to-mechanical energy conversion for exciting mechanical vibration in said apparatus; and
at least one sensor section having a sensor electrode with the electrical impedance of output static capacitance thereof matched to impedance of said load for optimized conversion of the energy of said excited mechanical vibration into electrical energy for driving said load; and
at least one feedback sensor having a predetermined shape function and located at a predetermined location on the workpiece of said transformer for feedback of information of said conversion in said apparatus for optimization control of said conversion, wherein
the length, width and thickness of said workpiece being geometrically proportional in predetermined direct ratio.

21. A method for constructing an optimized piezoelectric transformer comprising the steps of
determining transformer voltage step-up/down ratio;
determining transformer operating frequency and load-driving capability;
selecting piezoelectric transformer type most suitable for said determined step-up/down ratio and said operating frequency;
determining geometrical dimensions of said workpiece in direct ratio for said determined step-up/down ratio and said operating frequency;
matching impedance of the load driven by said transformer to output static capacitance of said transformer based on the geometry of the output of said transformer,
matching the modal strain under said operating frequency to a spatially-weighted modal actuator of said transformer.
